(19) United States
(12) Patent Application Publication
(10) Pub. No.: US 2004/0257124 A1
(43) Pub. Date: Dec. 23, 2004

(54) Spread spectrum clock generator capable of frequency modulation with high accuracy

(75) Inventors: Masahiro Araki, Hyogo (JP); Chieko Hayashi, Hyogo (JP)

Correspondence Address: McDermott, Will & Emery, 600 13th Street, N.W., Washington, DC, 20005-3096, US

(73) Assignees: RENESAS TECHNOLOGY CORP.; RENESAS LSI DESIGN CORPORATION

(21) Appl. No.: 10/873,309

(22) Filed: Jun. 23, 2004

(30) Foreign Application Priority Data
Jun. 23, 2003 (JP) 2003-178416(P)

(51) Int. Cl. H03C 3/00

(52) U.S. Cl. 327/101

(57) ABSTRACT

In a spread spectrum clock generator, a DLL circuit delays an oscillation clock signal from a VCO and outputs ten delay clock signals having different phases respectively. A selector selects any one of the ten delay clock signals, and outputs a selected clock signal. A control circuit controls a signal selection operation of the selector. A feedback frequency divider divides a frequency of the selected clock signal by a frequency division ratio N, and generates a comparison clock signal. In this manner, a phase of the comparison clock signal can be fine-tuned. Therefore, a spread spectrum clock generator capable of frequency modulation with high accuracy can be obtained.

### BACKGROUND OF THE INVENTION

1. Field of the Invention

The present invention relates to a clock generator, and more particularly to a spread spectrum clock generator.

2. Description of the Background Art

A spread spectrum clock generator (SSCG) modulates a frequency of an oscillation clock signal so as to spread a bandwidth of a clock signal. Accordingly, EMI (Electro Magnetic Interference) noise is lowered.

Some of conventional spread spectrum clock generators provided with a PLL (Phase Locked Loop) circuit include an input frequency divider dividing a frequency of an external clock signal and providing a reference clock signal to the PLL circuit, a feedback frequency divider dividing a frequency of an oscillation clock signal from an oscillator in the PLL circuit for feedback, and a control circuit modifying and controlling a frequency division ratio of the input frequency divider and the feedback frequency divider.

For example, U.S. Pat. No. 6,377,646 proposes a spread spectrum clock generator controlling a frequency division ratio of a feedback frequency divider using an ROM (Read Only Memory).

In addition, U.S. Pat. No. 6,292,507 proposes a spread spectrum clock generator observing an output signal from a phase comparator in a PLL circuit and controlling a variety of parameters based on an observation result.

As described above, the conventional spread spectrum clock generator has modified a multiplication factor of a frequency by controlling and modifying the frequency division ratio of the frequency divider, thereby attaining frequency modulation of the output clock signal. With such a method of controlling and modifying the frequency division ratio of the frequency divider, however, a frequency multiplication factor may be restricted by a value of the frequency division ratio. Therefore, fine tuning of the frequency may be difficult depending on a condition, and accuracy in frequency modulation has been insufficient.

### SUMMARY OF THE INVENTION

Accordingly, a primary object of the present invention is to provide a spread spectrum clock generator capable of frequency modulation with high accuracy.

A clock generator according to the present invention includes an internal clock generator generating an oscillation clock signal obtained by multiplying a frequency of a reference clock signal, in synchronization with the received reference clock signal. The internal clock generator includes: a phase comparator circuit comparing phases of the reference clock signal and an internally generated comparison clock signal and outputting a phase difference signal in accordance with a comparison result; an oscillation circuit generating the oscillation clock signal based on the phase difference signal; a delay circuit delaying the oscillation clock signal so as to generate a plurality of delay clock signals having different phases respectively; a selection circuit selecting and outputting any one of the plurality of delay clock signals; and a frequency divider dividing a frequency of an output signal from the selection circuit by a predetermined frequency division ratio so as to generate the comparison clock signal. Thus, the phase of the oscillation clock signal can finely be tuned. Therefore, a spread spectrum clock generator capable of frequency modulation with high accuracy can be implemented.

Another clock generator according to the present invention includes: a delay circuit delaying a received clock signal so as to generate a plurality of delay clock signals having different phases respectively; a selection circuit selecting and outputting any one of the plurality of delay clock signals; a frequency divider dividing a frequency of an output signal from the selection circuit by a predetermined frequency division ratio so as to generate a reference clock signal; and an internal clock generator generating an oscillation clock signal obtained by multiplying a frequency of the reference clock signal, in synchronization with the reference clock signal. Here again, the phase of the oscillation clock signal can finely be tuned. Therefore, a spread spectrum clock generator capable of frequency modulation with high accuracy can be implemented.

In addition, yet another clock generator according to the present invention includes: a first internal clock generator generating a first oscillation clock signal obtained by multiplying a frequency of a first reference clock signal, based on the received first reference clock signal; a first frequency divider dividing a frequency of the first oscillation clock signal by a predetermined frequency division ratio so as to generate a second reference clock signal; and a second internal clock generator generating a second oscillation clock signal obtained by multiplying a frequency of the second reference clock signal, in synchronization with the second reference clock signal. The first internal clock generator includes: a phase comparator circuit comparing phases of the first reference clock signal and an internally generated comparison clock signal and outputting a phase difference signal in accordance with a comparison result; an oscillation circuit generating a plurality of clock signals having different phases respectively based on the phase difference signal; a second frequency divider dividing a frequency of any one clock signal among the plurality of clock signals from the oscillation circuit by a predetermined frequency division ratio so as to generate the comparison clock signal; and a selection circuit selecting any one of the plurality of clock signals from the oscillation circuit and outputting the first oscillation clock signal. Here again, the phase of the oscillation clock signal can finely be tuned. Therefore, a spread spectrum clock generator capable of frequency modulation with high accuracy can be implemented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram schematically showing a configuration of a spread spectrum clock generator in a first embodiment of the present invention.

FIG. 2 is a circuit diagram showing a configuration of a DLL circuit shown in FIG. 1.

FIG. 3 is a timing chart illustrating an operation of a selector and the DLL circuit shown in FIG. 1.

FIG. 4 is a timing chart illustrating an operation of a feedback frequency divider shown in FIG. 1.

FIGS. 5A and 5B illustrate operations of a conventional spread spectrum clock generator respectively.

FIG. 6 is a block diagram schematically showing a configuration of a spread spectrum clock generator in a second embodiment of the present invention.

FIG. 7 is a block diagram schematically showing a configuration of a spread spectrum clock generator in a third embodiment of the present invention.

FIG. 8 is a circuit diagram showing a configuration of a VCO shown in FIG. 7.

FIG. 9 is a timing chart illustrating an operation of a selector and the VCO shown in FIG. 7.

### DESCRIPTION OF THE PREFERRED EMBODIMENTS

[First Embodiment]

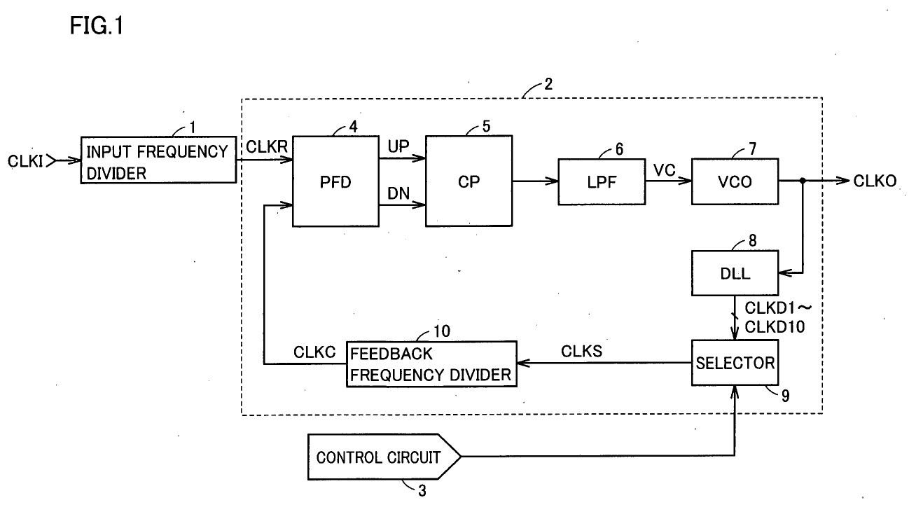

In FIG. 1, a spread spectrum clock generator in the first embodiment includes an input frequency divider 1, a PLL circuit 2 and a control circuit 3.

PLL circuit 2 includes a phase frequency comparator (PFD) 4, a charge pump (CP) 5, a loop filter (LPF) 6, a VCO (Voltage Controlled Oscillator) 7, a DLL (Delay Locked Loop) circuit 8, a selector 9, and a feedback frequency divider 0. PLL circuit 2 serves as an oscillation circuit causing an oscillator in the loop to oscillate through feedback control, so that a phase difference between an external reference clock signal and a comparison clock signal from the oscillator in the loop is constant.

Input frequency divider 1 divides-a frequency of an external clock signal CLK1 by a frequency division ratio M (1/M frequency division) so as to generate a reference clock signal CLKR. Phase frequency comparator 4 detects a rising edge difference between reference clock signal CLKR from input frequency divider 1 and a comparison clock signal CLKC from feedback frequency divider 10, and outputs phase difference signals UP, DN having a pulse width in accordance with a detection result. Charge pump 5 supplies a positive current in response to phase difference signal UP from phase frequency comparator 4, and supplies a negative current in response to phase difference signal DN. Loop filter 6 integrates an output current from charge pump 5 and outputs a control voltage VC. VCO 7 generates an oscillation clock signal CLKO having a frequency in accordance with control voltage VC from loop filter 6.

DLL circuit 8 delays oscillation clock signal CLKO from VCO 7, and outputs delay clock signals CLKD1 to CLKD10 having different phases respectively. Selector 9 selects any one of delay clock signals CLKD1 to CLKD10 from DLL circuit 8, and outputs a selected clock signal CLKS. Control circuit 3 controls a signal selection operation of selector 9. Feedback frequency divider 10 divides a frequency of selected clock signal CLKS from selector 9 by a frequency division ratio N (1/N frequency division), and generates comparison clock signal CLKC.

The spread spectrum clock generator slightly varies the frequency of the oscillation clock signal, so as to spread the bandwidth of the clock signal. In the following, a circuit configuration and an operation for slightly varying the frequency of the oscillation clock signal will be described.

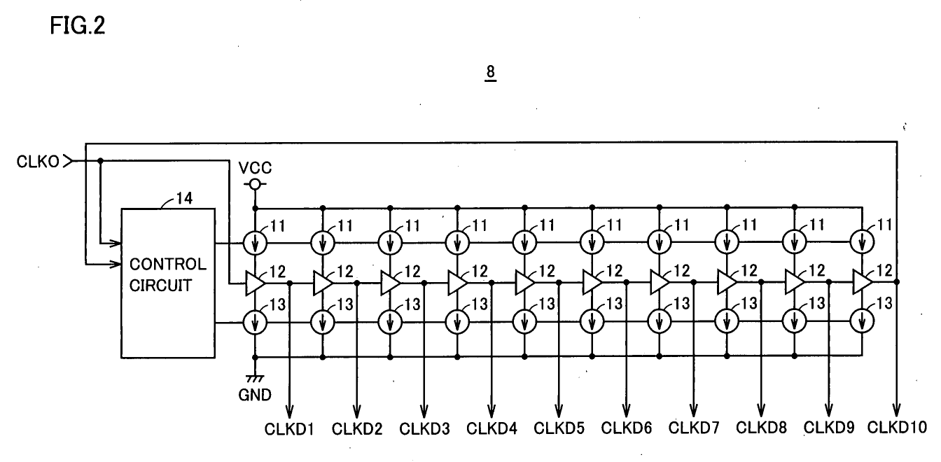

In FIG. 2, DLL circuit 8 includes ten current sources 11, ten buffer circuits 12, ten current sources 13, and a control circuit 14.

Ten buffer circuits 12 are connected in series, and delay oscillation clock signal CLKO from VCO 7. A corresponding current source 11 is connected between a line of a power supply potential VCC and a power supply terminal of each buffer circuit 12. A corresponding current source 13 is connected between a ground terminal of each buffer circuit 12 and a line of a ground potential GND. A delay time of each buffer circuit 12 is determined by corresponding current sources 11, 13. Delay clock signals CLKD1 to CLKD10 are output from an output node of each buffer circuit 12.

Control circuit 14 compares the phase of oscillation clock signal CLKO from VCO 7 with the phase of delay clock signal CLKD10 from buffer circuit 12 at the last stage, and controls current values of current sources 11, 13 so that the phase difference therebetween is equal to one cycle of oscillation clock signal CLKO.

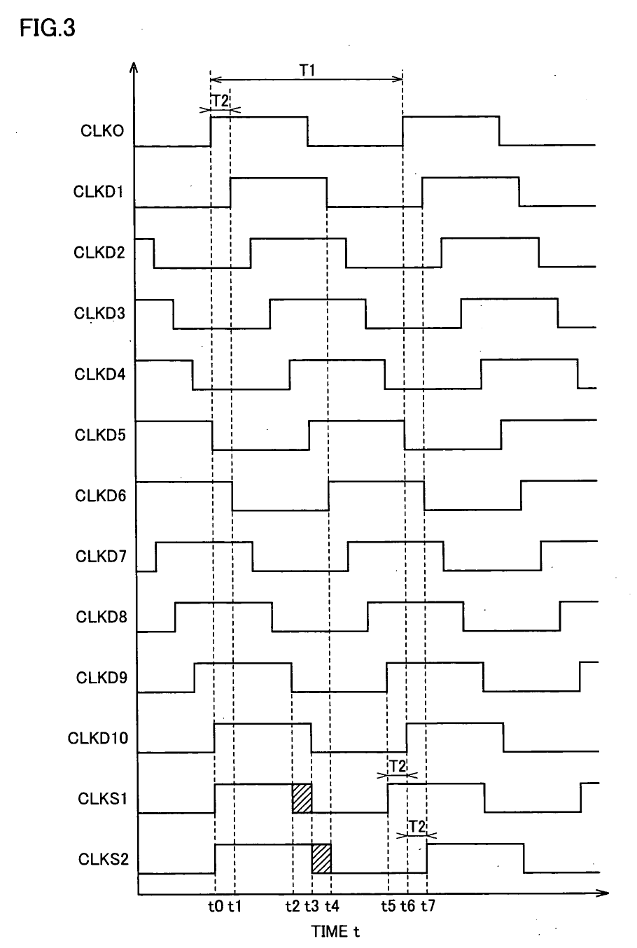

FIG. 3 is a timing chart illustrating an operation of selector 9 and DLL circuit 8 shown in FIG. 1. In FIG. 3, oscillation clock signal CLKO represents a signal output from VCO 7, delay clock signals CLKD1 to CLKD10 represent signals output from DLL circuit 8, and selected clock signals CLKS1, CLKS2 represent signals output from selector 9.

Oscillation clock signal CLKO has a cycle T1. Delay clock signal CLKD1 from buffer circuit 12 at the first stage exhibits a waveform of which phase lags behind oscillation clock signal CLKO by a time T2. Time T2 represents a time obtained by dividing cycle T1 into ten parts. Delay clock signal CLKD2 from buffer circuit 12 at a next stage exhibits a waveform of which phase lags behind delay clock signal CLK1 by time T2. Similarly, delay clock signals CLKD3 to CLKD10 exhibit waveforms of which respective phases lag by time T2 sequentially. Delay clock signal CLKD 10 exhibits a waveform of which phase lags behind oscillation clock signal CLKO by time T1.

Selector 9 selects any one of delay clock signals CLKD1 to CLKD10 from DLL circuit 8, and outputs selected clock signal CLKS. A selection operation of selector 9 is controlled by control circuit 3.

Selected clock signal CLKS1 represents a signal output from selector 9 when selector 9 switches the selected signal from delay clock signal CLKD10 to delay clock signal CLKD9. Here, it is assumed that the selected signal is switched during a period from time t0 to time t5. Then, the waveform of selected clock signal CLKS 1 coincides with the waveform of delay clock signal CLKD 10 until a time of switch, and coincides with the waveform of delay clock signal CLKD9 after the time of switch. In other words, the selected clock signal rises to H level at time t0, falls to L level at time t2 or t3, and rises to H level at time t5. Therefore, the phase of selected clock signal CLKS1 leads by time T2. Note that a hatched portion of the waveform of selected clock signal CLKS1 indicates that any of delay clock signal CLKD10 and delay clock signal CLKD9 may be selected at that time.

Selected clock signal CLKS2 represents a signal output from selector 9 when selector 9 switches the selected signal from delay clock signal CLKD10 to delay clock signal CLKD1. Here, it is assumed that the selected signal is switched during a period from time t1 to time t6. Then, the waveform of selected clock signal CLKS2 coincides with the waveform of delay clock signal CLKD10 until the time of switch, and coincides with the waveform of delay clock signal CLKD1 after the time of switch. In other words, the selected clock signal rises to H level at time t0, falls to L level at time t3 or t4, and rises to H level at time t7. Therefore, the phase of selected clock signal CLKS2 lags by time T2. Note that a hatched portion of the waveform of selected clock signal CLKS2 indicates that any of delay clock signal CLKD10 and delay clock signal CLKD1 may be selected at that time.

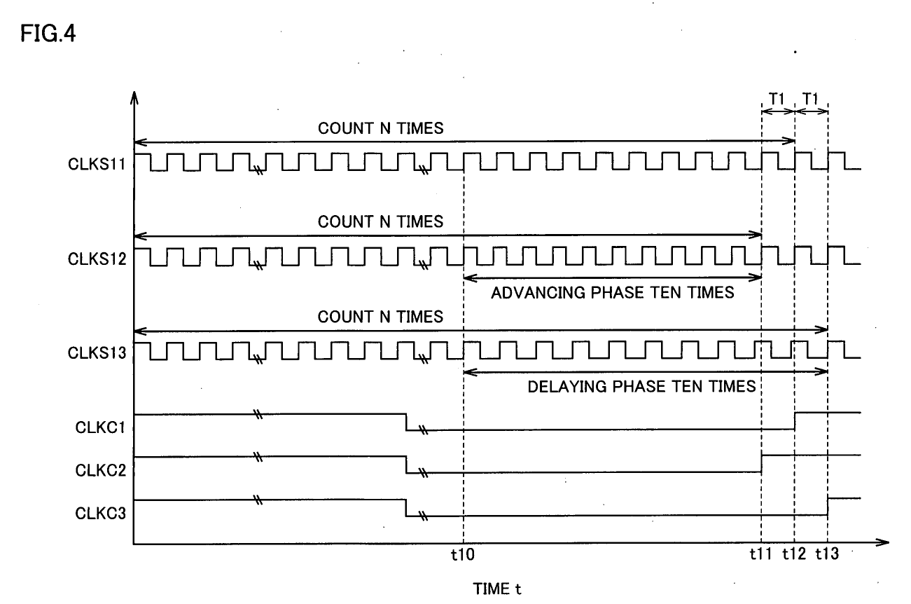

FIG. 4 is a timing chart illustrating an operation of feedback frequency divider 10 shown in FIG. 1. In FIG. 4, selected clock signals CLKS11 to CLKS13 represent signals output from selector 9, and comparison clock signals CLKC1 to CLKC3 represent signals output from feedback frequency divider 10.

Selected clock signal CLKS11 is a signal output from selector 9 when selector 9 does not perform an operation to switch the selected signal. Here, feedback frequency divider 10 counts a pulse of selected clock signal CLKS11 N times until time t12. Feedback frequency divider 10 divides a frequency of selected clock signal CLKS11 by frequency division ratio N, so as to generate comparison clock signal CLKC1.

Selected clock signal CLKS12 is a signal output from selector 9 when selector 9 performs the operation to switch the selected signal ten times in a phase lead direction. In other words, selector 9 switches the selected signal at time t10 from delay clock signal CLKD10 to delay clock signal CLKD9, then from delay clock signal CLKD9 to delay clock signal CLKD8, and then from delay clock signal CLKD8 to delay clock signal CLKD7. Such switching operations are repeated ten times until time t11. In the tenth switching operation, the selected signal of selector 9 is switched from delay clock signal CLKD1 to delay clock signal CLKD10. Here, feedback frequency divider 10 counts a pulse of selected clock signal CLKS12 N times until time t11. Feedback frequency divider 10 divides a frequency of selected clock signal CLKS12 by frequency division ratio N, so as to generate comparison clock signal CLKC2. Comparison clock signal CLKC2 exhibits a waveform of which phase leads comparison clock signal CLKC1 by time T1 (comparable to one cycle of oscillation clock signal CLKO).

Though not shown, when selector 9 performs the operation to switch the selected signal only once in the phase lead direction, comparison clock signal CLKC exhibits a waveform of which phase leads comparison clock signal CLKC1 by 1/10 of time T1 (comparable to 1/10 cycle of oscillation clock signal CLKO). The operation to switch the selected signal by selector 9 is arbitrarily controlled by control circuit 3. Therefore, the phase of comparison clock signal CLKC can lead by a unit of 1/10 of cycle T1 of oscillation clock signal CLKO.

Selected clock signal CLKS13 is a signal output from selector 9 when selector 9 performs the operation to switch the selected signal ten times in a phase lag direction. In other words, selector 9 switches the selected signal at time t10 from delay clock signal CLKD10 to delay clock signal CLKD1, then from delay clock signal CLKD1 to delay clock signal CLKD2, and then from delay clock signal CLKD2 to delay clock signal CLKD3. Such switching operations are repeated ten times until time t13. In the tenth switching operation, the selected signal of selector 9 is switched from delay clock signal CLKD9 to delay clock signal CLKD10. Here, feedback frequency divider 10 counts a pulse of selected clock signal CLKS13 N times until time t13. Feedback frequency divider 10 divides a frequency of selected clock signal CLKS 13 by frequency division ratio N, so as to generate comparison clock signal CLKC3. Comparison clock signal CLKC3 exhibits a waveform of which phase lags behind comparison clock signal CLKC1 by time T1 (comparable to one cycle of oscillation clock signal CLKO).

Though not shown, when selector 9 performs the operation to switch the selected signal only once in the phase lag direction, comparison clock signal CLKC exhibits a waveform of which phase lags behind comparison clock signal CLKC1 by 1/10 of time T1 (comparable to 1/10 cycle of oscillation clock signal CLKO). The operation to switch the selected signal by selector 9 is arbitrarily controlled by control circuit 3. Therefore, the phase of comparison clock signal CLKC can lag by a unit of 1/10 of cycle T1 of oscillation clock signal CLKO.

Here, if the operation speed of selector 9 to switch the selected signal is sufficiently fast and a spike does not occur in output clock signal CLKS from selector 9, the operation to switch the selected signal may be performed such that the phase is varied at one time by not smaller than 2/10 of time T1.

Therefore, the phase of comparison clock signal CLKC can be adjusted in any unit not smaller than 1/10 of cycle T1 of oscillation clock signal CLKO.

In order to attain frequency modulation of oscillation clock signal CLKO, the conventional spread spectrum clock generator has modified a multiplication factor of a frequency by controlling and modifying the frequency division ratio of input frequency divider 1 and/or feedback frequency divider 10 without using DLL circuit 8 and selector 9.

Here, for comparison with the operation of the spread spectrum clock generator in the first embodiment, an operation of the conventional spread spectrum clock generator will now be described.

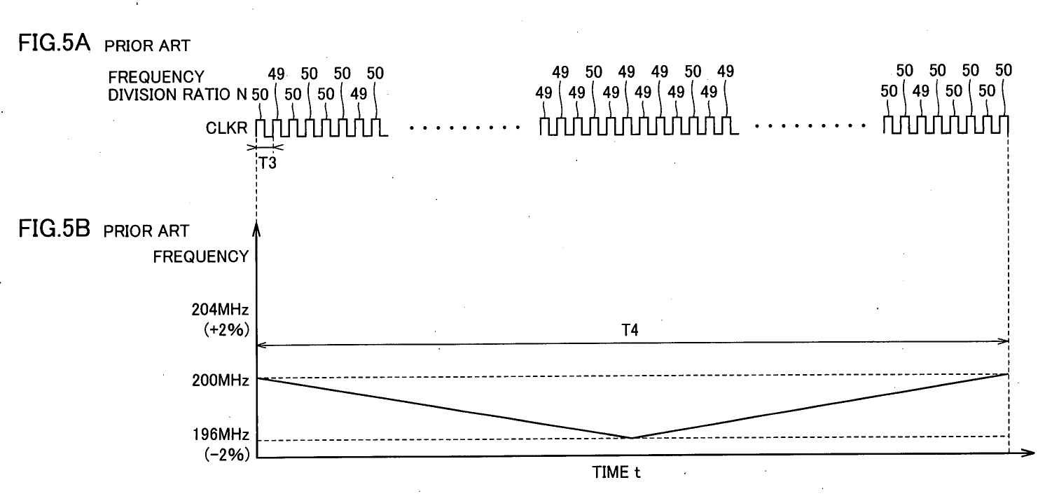

FIGS. 5A and 5B illustrate operations of the conventional spread spectrum clock generator respectively. FIG. 5A illustrates an operation to modify frequency division ratio N of the feedback frequency divider, while FIG. 5B illustrates oscillation clock signal CLKO of which frequency has been modulated to a triangular waveform.

Here, it is assumed that clock signal CLK1 externally input to the input frequency divider has a frequency of 200 MHz and frequency division ratio M of the input frequency divider is set to 50. When frequency division ratio N of the feedback frequency divider is held at 50, the frequency of generated oscillation clock signal CLKO is set to 200 MHz. When frequency division ratio N of the feedback frequency divider is held at 49, the frequency of generated oscillation clock signal CLKO is set to 196 MHz (modulation amplitude: −2%).

Here, a cycle T3 of reference clock signal CLKR generated by the input frequency divider is set to 250 ns. When a modulation cycle during which a frequency is modulated to a triangle waveform is assumed as T4, phase comparison operations by the phase frequency comparator are performed (T4/T3) times during time T4. As shown in FIG. 5A, frequency division ratio N of the feedback frequency divider is controlled and modified to 50 or 49 for each cycle T3 of reference clock signal CLKR. Thus, as shown in FIG. 5B, oscillation clock signal CLKO of which frequency has been modulated (modulation amplitude: −2%) to a triangular waveform in a range from 200 MHz to 196 MHz is generated. If the number of times that the frequency division ratio N of the feedback frequency divider is set to 50 is equal to the number of times that the frequency division ratio N of the feedback frequency divider is set to 49, the waveform of oscillation clock signal CLKO approaches an ideal smooth waveform.

If modulation cycle T4 is set to 40 μs, for example, the number of phase comparison operations by the phase frequency comparator is set to (T4/T3)=160. The larger the number of phase comparison operations is, the smoother the waveform of oscillation clock signal CLKO will be. On the other hand, if shorter modulation cycle T4 (20 μs, for example) is desired, the number of phase comparison operations by the phase frequency comparator is reduced, that is, set to (T4/T3)=80. Accordingly, the waveform of generated oscillation clock signal CLKO will be less smooth.

Though not shown, when clock signal CLKI externally input to the input frequency divider has a frequency of 200 MHz and frequency division ratio M of the input frequency divider is set to 20, generated reference clock signal CLKR has cycle T3 of 100 ns. If frequency division ratio N of the feedback frequency divider is controlled and modified to 20 or 19 for each cycle T3 of reference clock signal CLKR, oscillation clock signal CLKO of which frequency is modulated (modulation amplitude: −5%) to a triangular waveform in a range from 200 MHz to 190 MHz is generated. If modulation cycle T4 is set to 20 μs, for example, the number of phase comparison operations by the phase frequency comparator is set to (T4/T3)=200. Under this condition, if frequency modulation (modulation amplitude: −2%) of generated signal CLKO to a triangular waveform in a range from 200 MHz to 196 MHz is desired, the number of times that frequency division ratio N of the feedback frequency divider is set to 20 is increased while the number of times that frequency division ratio N of the feedback frequency divider is set to 19 is decreased, among 200 times of phase comparison operations by the phase frequency comparator. On the other hand, if there is a difference between the number of times that frequency division ratio N of the feedback frequency divider is set to 20 and the number of times that it is set to 19, the waveform of generated oscillation clock signal CLKO will be less smooth.

As described above, with such a method of controlling and modifying the frequency division ratio of the input frequency divider and/or the feedback frequency divider as in the conventional spread spectrum clock generator, a frequency multiplication factor is restricted by the frequency division ratio. Therefore, fine-tuning of the frequency may be difficult depending on a condition, and accuracy in frequency modulation has been insufficient.

On the other hand, in the first embodiment, the phase of comparison clock signal CLKC can be adjusted by a unit of 1/10 of cycle T1 of oscillation clock signal CLKO. Referring to FIG. 4, varying frequency division ratio N of feedback frequency divider 10 by 1 as in the conventional example is comparable to operations of ten times to switch the selected signal by selector 9. In other words, adjustment of the phase of comparison clock signal CLKC by a unit of 1/10 of cycle T1 of oscillation clock signal CLKO is comparable to varying frequency division ratio N of feedback frequency divider 10 by 0.1.

For example, when clock signal CLK1 externally input to input frequency divider 1 has a frequency of 200 MHz and frequency division ratios M, N of input frequency divider 1 and feedback frequency divider 10 are both set to 50, reference clock signal CLKR generated by input frequency divider 1 has cycle T3 of 250 ns. When selector 9 performs an operation to switch the selected signal so that the phase of comparison clock signal CLKC leads by 1/10 of cycle T1 of oscillation clock signal CLKO, oscillation clock signal CLKO of which frequency has been modulated (modulation amplitude: −0.2%) to a triangular waveform in a range from 200 MHz to 199.6 MHz is generated. In this case, modulation amplitude attains 1/10 of that in the conventional example. In other words, the phase of oscillation clock signal CLKO can be adjusted with accuracy 10 times as high as in the conventional example.

In addition, when clock signal CLKI externally input to input frequency divider 1 has a frequency of 200 MHz and frequency division ratios M, N of input frequency divider 1 and feedback frequency divider 10 are both set to 5, reference clock signal CLKR generated by input frequency divider 1 has cycle T3 of 25 ns. When selector 9 performs an operation to switch the selected signal so that the phase of comparison clock signal CLKC leads by 1/10 of cycle T1 of oscillation clock signal CLKO, oscillation clock signal CLKO of which frequency has been modulated (modulation amplitude: −2%) to a triangular waveform in a range from 200 MHz to 196 MHz is generated. Here, if modulation cycle T4 is set to 20 μs, the number of phase comparison operations by phase frequency comparator 4 is set to (T4/T3)=800. In this case, the number of phase comparison operations by phase frequency comparator 4 is ten times as large as that in the conventional example. In other words, the phase of oscillation clock signal CLKO can be adjusted with accuracy 10 times as high as in the conventional example.

Though the example in which the number of stages of buffer circuits 12 in DLL circuit 8 is set to 10 has been described in the present embodiment, the same effect will be obtained even if the number of stages of buffer circuits 12 in DLL circuit 8 is set to any value. Therefore, if the number of stages of buffer circuits 12 is increased, accuracy in adjusting the phase of oscillation clock signal CLKO can further be improved.

As described above, in the first embodiment, a spread spectrum clock generator capable of frequency modulation with high accuracy can be implemented by providing DLL circuit 8, selector 9 and control circuit 3.

[Second Embodiment]

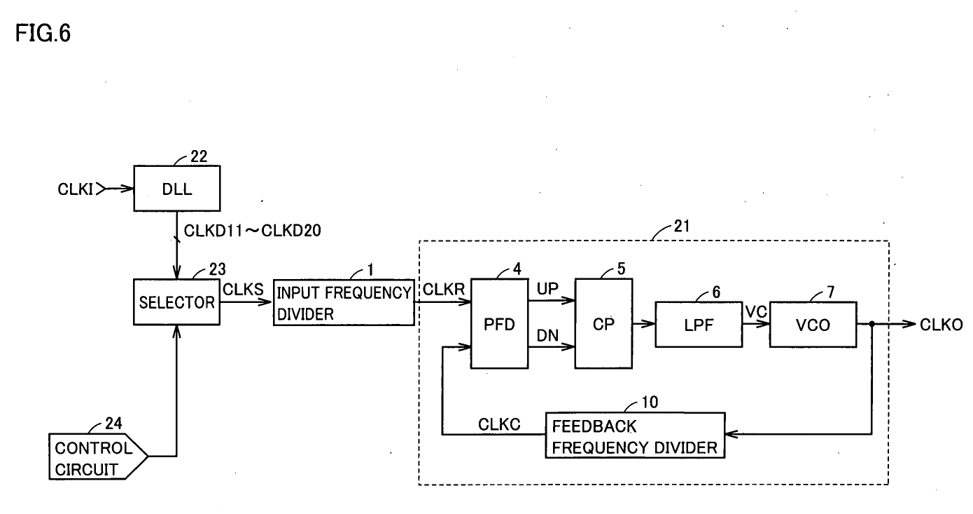

In FIG. 6, a spread spectrum clock generator in the second embodiment includes input frequency divider 1, a PLL circuit 21, a DLL circuit 22, a selector 23, and a control circuit 24.

PLL circuit 21 includes phase frequency comparator 4, charge pump 5, loop filter 6, VCO 7, and feedback frequency divider 10. Referring to PLL circuit 21, PLL circuit 21 is different from PLL circuit 2 in FIG. 1 in that control circuit 3, DLL circuit 8 and selector 9 are not provided.

Feedback frequency divider 10 divides the frequency of oscillation clock signal CLKO from VCO 7 by frequency division ratio N, and generates comparison clock signal CLKC. PLL circuit 21 serves as an oscillation circuit causing the oscillator in the loop to oscillate through feedback control, so that a phase difference between reference clock signal CLKR from input frequency divider 1 and comparison clock signal CLKC from the oscillator in the loop is constant.

Similarly to DLL circuit 8 shown in FIG. 2, DLL circuit 22 is formed by current sources and buffer circuits of ten stages. DLL circuit 22 delays external clock signal CLK1 and outputs delay clock signals CLKD11 to CLKD20 having different phases respectively. Delay clock signals CLKD11 to CLKD20 are signals of which phases are shifted by 1/10 of a cycle of clock signal CLK1, similarly to delay clock signals CLKD1 to CLKD10 of DLL circuit 8 shown in FIG. 3.

Selector 23 selects any one of delay clock signals CLKD11 to CLKD20 from DLL circuit 22, and outputs selected clock signal CLKS. Control circuit 24 controls an operation to switch the selected signal by selector 23. Input frequency divider 1 divides the frequency of selected clock signal CLKS from selector 23 by frequency division ratio M so as to generate reference clock signal CLKR.

With the configuration above, the phase of reference clock signal CLKR can arbitrarily be adjusted by a unit of 1/10 of the cycle of external clock signal CLK1. In other words, the phase of oscillation clock signal CLKO can be adjusted with accuracy 10 times as high as in the conventional example.

Though the example in which the number of stages of the buffer circuits in DLL circuit 12 is set to 10 has been described in the present embodiment, the same effect will be obtained even if the number of stages of the buffer circuits in DLL circuit 22 is set to any value. Therefore, if the number of stages of the buffer circuits is increased, accuracy in adjusting the phase of oscillation clock signal CLKO of PLL circuit 21 can further be improved.

As described above, in the second embodiment, a spread spectrum clock generator capable of frequency modulation with high accuracy can be implemented by providing DLL circuit 22, selector 23 and control circuit 24.

[Third Embodiment]

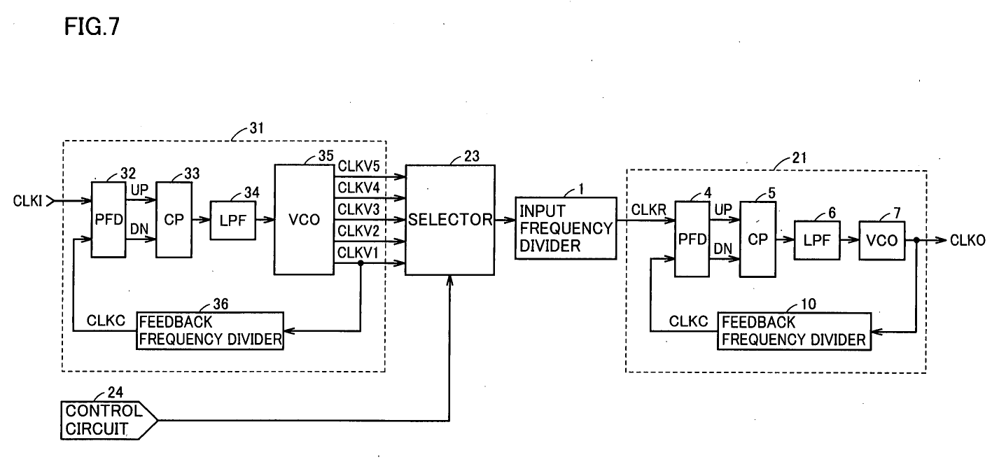

Referring to a spread spectrum clock generator according to the third embodiment in FIG. 7, this spread spectrum clock generator is different from the spread spectrum clock generator in FIG. 6 in that DLL circuit 22 is replaced with a PLL circuit 31.

PLL circuit 31 includes a phase frequency comparator 32, a charge pump 33, a loop filter 34, a VCO 35, and a feedback frequency divider 36. PLL circuit 31 serves as an oscillation circuit causing the oscillator in the loop to oscillate through feedback control, so that a phase difference between external clock signal CLK1 and comparison clock signal CLKC from the oscillator in the loop is constant. PLL circuit 31 generates clock signals CLKV1 to CLKV5 having different phases respectively, and outputs those signals to selector 23.

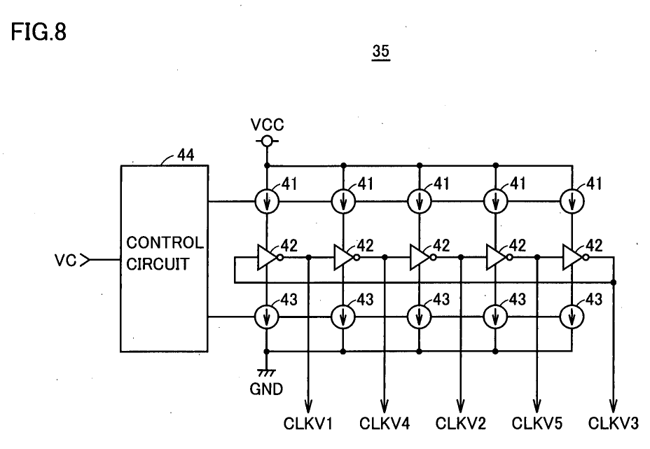

In FIG. 8, VCO 35 includes five current sources 41, five inverter circuits 42, five current sources 43, and a control circuit 44.

Five inverter circuits 42 are connected in series in a ring shape, so as to form a ring oscillator. A corresponding current source 41 is connected between a line of power supply potential VCC and a power supply terminal of each inverter circuit 42. A corresponding current source 43 is connected between a ground terminal of each inverter circuit 42 and a line of ground potential GND. A delay time of each inverter circuit 42 is determined by corresponding current sources 41, 43. Clock signals CLKV1 to CLKV5 are output from an output node of each inverter circuit 42.

Control circuit 44 controls a current value of current sources 41, 43 in accordance with control voltage VC from loop filter 34, so as to adjust an oscillation frequency of the ring oscillator.

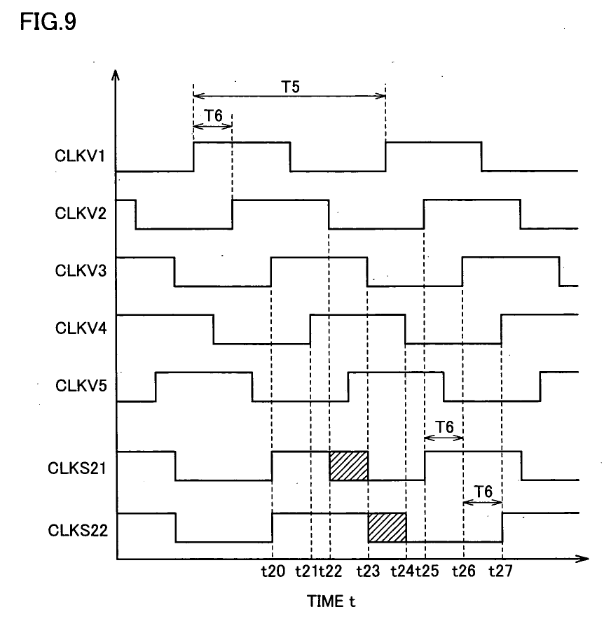

FIG. 9 is a timing chart illustrating an operation of selector 23 and VCO 35 shown in FIG. 7. In FIG. 9, clock signals CLKV1 to CLKV5 represent signals output from VCO 35, while selected clock signals CLKS21, CLKS22 represent signals output from selector 23.

Clock signals CLKV1 to CLKV5 have a cycle T5. Output clock signal CLKV2 from inverter circuit 42 at the third stage is delayed by a time delayed by two inverter circuits 42, as compared with output clock signal CLKV1 of inverter circuit 42 at the first stage. Therefore, output clock signal CLKV2 exhibits a waveform of which phase lags behind clock signal CLKV1 by time T6 (⅕ of cycle T5). In this manner, respective phases of clock signals CLKV3 to CLKV5 sequentially lag by time T6.

Selector 23 selects any one of output clock signals CLKV1 to CLKV 5 from VCO 35, and outputs selected clock signal CLKS. A selection operation of selector 23 is controlled by control circuit 24.

Selected clock signal CLKS21 represents a signal output from selector 23 when selector 23 switches the selected signal from clock signal CLKV3 to clock signal CLKV2. Here, it is assumed that the selected signal is switched during a period from time t20 to time t25. Then, the waveform of selected clock signal CLKS21 coincides with the waveform of clock signal CLKV3 until the time of switch, and coincides with the waveform of clock signal CLKV2 after the time of switch. In other words, the selected clock signal rises to H level at time t20, falls to L level at time t22 or t23, and rises to H level at time t25. Therefore, the phase of selected clock signal CLKS21 leads by time T6. Note that a hatched portion of the waveform of selected clock signal CLKS21 indicates that any of clock signal CLKV3 and clock signal CLKV2 may be selected at that time.

Selected clock signal CLKS22 represents a signal output from selector 23 when selector 23 switches the selected signal from clock signal CLKV3 to clock signal CLKV4. Here, it is assumed that the selected signal is switched during a period from time t21 to time t26. Then, the waveform of selected clock signal CLKS22 coincides with the waveform of clock signal CLKV3 until the time of switch, and coincides with the waveform of clock signal CLKV4 after the time of switch. In other words, the selected clock signal rises to H level at time t20, falls to L level at time t23 or t24, and rises to H level at time t27. Therefore, the phase of selected clock signal CLKS22 from selector 23 lags by time T6. Note that a hatched portion of the waveform of selected clock signal CLKS22 indicates that any of clock signal CLKV3 and clock signal CLKV4 may be selected at that time.

Therefore, the phase of reference clock signal CLKR input to PLL circuit 21 can arbitrarily be adjusted by a unit of ⅕ of the cycle of clock signal CLKV from PLL circuit 31. In other words, the phase of oscillation clock signal CLKO of PLL circuit 21 can be adjusted with accuracy five times as high as in the conventional example.

Though the example in which the number of stages of inverter circuits 42 in VCO 35 is set to 5 has been described in the present embodiment, the same effect will be obtained provided that the number of stages of inverter circuits 42 in VCO 35 is set to any odd number. Therefore, if the number of stages of inverter circuits 42 is increased, accuracy in adjusting the phase of oscillation clock signal CLKO of PLL circuit 21 can further be improved.

As described above, in the third embodiment, a spread spectrum clock generator capable of frequency modulation with high accuracy can be implemented by providing PLL circuit 31, selector 23 and control circuit 24.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A spread spectrum clock generator, comprising:
an internal clock generator generating an oscillation clock signal obtained by multiplying a frequency of a reference clock signal, in synchronization with received said reference clock signal; wherein
said internal clock generator includes
a phase comparator circuit comparing phases of said reference clock signal and an internally generated comparison clock signal and outputting a phase difference signal in accordance with a comparison result,
an oscillation circuit generating said oscillation clock signal based on said phase difference signal,
a delay circuit delaying said oscillation clock signal so as to generate a plurality of delay clock signals having different phases respectively,
a selection circuit selecting and outputting any one of said plurality of delay clock signals, and
a frequency divider dividing a frequency of an output signal from said selection circuit by a predetermined frequency division ratio so as to generate said comparison clock signal.

2. The clock generator according to claim 1, wherein
said delay circuit includes
a plurality of buffer circuits connected in series and outputting said plurality of delay clock signals respectively, in response to reception of said oscillation clock signal at a buffer circuit at a first stage, and
a control circuit controlling a delay time of said plurality of buffer circuits so that a phase difference between said oscillation clock signal and a delay clock signal from a buffer circuit at a last stage among said plurality of buffer circuits is equal to one cycle of said oscillation clock signal.

3. A spread spectrum clock generator, comprising:
a delay circuit delaying a received clock signal so as to generate a plurality of delay clock signals having different phases respectively,
a selection circuit selecting and outputting any one of said plurality of delay clock signals,
a frequency divider dividing a frequency of an output signal from said selection circuit by a predetermined frequency division ratio so as to generate a reference clock signal, and
an internal clock generator generating an oscillation clock signal obtained by multiplying a frequency of said reference clock signal, in synchronization with said reference clock signal.

4. The clock generator according to claim 3, wherein
said delay circuit includes
a plurality of buffer circuits connected in series and outputting said plurality of delay clock signals respectively, in response to reception of said oscillation clock signal at a buffer circuit at a first stage, and
a control circuit controlling a delay time of said plurality of buffer circuits so that a phase difference between said received clock signal and a delay clock signal from a buffer circuit at a last stage among said plurality of buffer circuits is equal to one cycle of said received clock signal.

5. A spread spectrum clock generator, comprising:
a first internal clock generator generating a first oscillation clock signal obtained by multiplying a frequency of a first reference clock signal, based on received said first reference clock signal;
a first frequency divider dividing a frequency of said first oscillation clock signal by a predetermined frequency division ratio so as to generate a second reference clock signal; and
a second internal clock generator generating a second oscillation clock signal obtained by multiplying a frequency of said second reference clock signal, in synchronization with said second reference clock signal; wherein
said first internal clock generator includes
a phase comparator circuit comparing phases of said first reference clock signal and an internally generated comparison clock signal and outputting a phase difference signal in accordance with a comparison result,
an oscillation circuit generating a plurality of clock signals having different phases respectively based on said phase difference signal,
a second frequency divider dividing a frequency of any one clock signal among said plurality of clock signals from said oscillation circuit by a predetermined frequency division ratio so as to generate said comparison clock signal, and
a selection circuit selecting any one of said plurality of clock signals from said oscillation circuit and outputting said first oscillation clock signal.

6. The clock generator according to claim 5, wherein
said oscillation circuit includes
a plurality of inverters connected in series in a ring shape and outputting said plurality of clock signals respectively, and
a control circuit controlling an oscillation frequency of a ring oscillator formed by said plurality of inverters.
